(19) United States
(12) Patent Application Publication
(10) Pub. No.: US 2011/0101473 A1
(43) Pub. Date: May 5, 2011

(54) Junction deveice

(76) Inventors: Yen-Wei Hsu, Taipei (TW); Whei-Chyou Wu, Fremont, CA (US)

(21) Appl. No.: 12/611,122

(22) Filed: Nov. 3, 2009

(51) Int. Cl. H01L 29/06; H01L 29/66

(52) U.S. Cl. 257/414; 257/653; 257/E29.022; 257/E29.166

(57) ABSTRACT

This invention relates to a junction device, especially a p-n junction device. This invention also relates to a backward current decoupler which is also a good sensor. An induced backward current by forward current input can be decoupled by the backward current decoupler. The new p-n junction device has built-in damper and better capacitive property so that less power is consumed. The new sensor can be interactable with thermal, magnetic, optical, force or electrical fields.

### FIELD OF INVENTION

This invention relates to a junction device, especially a p-n junction device. This invention also relates to a backward current decoupler which can be a good sensor.

### BACKGROUND INFORMATION

The p-n junction device is the basic structure to almost all the transistor devices such as DRAM, CPU, LED and solar-cell, etc. The traditional p-n junction device is a PDR device having big resistance but small capacitance, which consumes more real power. The inventive p-n junction device has damper built in and more capacitive property so that it consumes less real power. The inventive p-n junction device is also a backward current decoupler which can decouple backward current from forward current. The invention has also defined a couple of backward current decouplers which can be good sensors for temperature field, magnetic field flux intensity, optical field intensity, electrical field such as voltage, current, frequency or electrical power, mechanical field such as magnitude of force, vibration force or any combinations of them.

### INTRODUCTION

Referring to [5], [34], [42, Vol. 1 Chapter 50] and [24, Page 402], the nonlinear system response produces many un-modeled effects: jump or singularity, bifurcation, rectification, harmonic and subharmonic generations, frequency-amplitude relationship, phase-amplitude relationship, frequency entrainment, nonlinear oscillation, stability, modulations (amplitude, frequency, phase) and chaoes. In the nonlinear analysis fields, it needs to develop the mathematical tools for obtaining the resolution of nonlinearity. Up to now, there exists three fundamental problems which are self-adjoint operator, spectral (harmonic) analysis, and scattering problems, referred to [32, Chapter 4.], [38, Page 303], [35, Chapter X], [37, Chapter XI], [36, Chapter XIII], [25] and [34, Chapter 7.].

There are many articles involved the topics of the nonlinear spectral analysis and reviewed as the following sections.

TABLE 1
Mechanical v.s. Electrical Systems

| Mechanical Systems | | Electrical Systems | |
|---|---|---|---|
| m | mass | L | inductance |
| y | displacement | q | charge |
| $\frac{dy}{dt} = v$ | velocity | $\frac{dq}{dt} = i$ | current |
| c | damping | R | resistance |
| k | spring constant | $\frac{1}{C}$ | reciprocal of capacitance |
| f (t) | input or driving force | E (t) | input or electromotive force |

The first one is the nonlinear dynamics and self-excited or self-oscillation systems. It provides a profound viewpoint of the non-linear dynamical system behaviors, which are duality of second-order systems, self-excitation, orbital equivalence or structural stability, bifurcation, perturbation, harmonic balance, transient behaviors, frequency-amplitude and phase-amplitude relationships, jump phenomenon or singularity occurrence, frequency entrainment or synchronization, and so on. In particular, the self-induced current (voltage) or electricity generation appears if applying to the Liénard system.

### Comparison Between Electrical and Mechanical Systems

Referred to [3, Page 341], the comparison between mechanical and electrical systems as the table (1):
the damping coefficient “c” in a mechanical system is analogous to “R” in an electrical system such that the resistance R, in common, could be as a energy dissipative device. There exists a series problem caused by the analogy between the mechanical and electrical systems. As a result, the damping term has to be a specific bandwidth of frequency response and just behaved an absorbent property as the previous definitions. The resistance has neither to be the frequency response nor absorbing but just had the balance or circle feature only. This is a crucial misunderstanding for two analogous systems.

### Dielectric Materials

Referring to [31, Chapter 4, 5, 8, 9], [20, Part One], [21, Chapter 1], [8, Chapter 14], the response of a material to an electric field can be used to advantage even when no charge is transferred. These effects are described by the dielectric properties of the material. Dielectric materials pons a large energy gap between the valence and conduction bands, thus the materials a high electrical resistivity. Because dielectric materials are used in the AC circuits, the dipoles must be able to switch directions, often in the high frequencies, where the dipoles are atoms or groups of atoms that have an unbalanced charge. Alignment of dipoles causes polarization which determines the behavior of the dielectric material. Electronic and ionic polarization occur easily even at the high frequencies. Some energy is lost as heat when a dielectric material polarized in the AC electric field. The fraction of the energy lost during each reversal is the dielectric loss. The energy losses are due to current leakage and dipoles friction (or change the direction). Losses due to the current leakage are low if the electrical resistivity is high, typically which behaves 10¹¹ Ohm·m or more. Dipole friction occurs when reorientation of the dipoles is difficult, as in complex organic molecules. The greatest loss occurs at frequencies where the dipoles almost, but not quite, can be reoriented. At lower frequencies, losses are low because the dipoles have time to move. At higher frequencies, losses are low because the dipoles do not move at all.

For a capacitor made from dielectric ceramics, referred to [20, Part One], [21, Chapter 1], [31, Page 253-255], its capacitance C, which is equivalent to one ideal capacitor Cᵢ and series resistance Rₛ in the FIG. 5, is function of frequency ω, equivalent series resistance Rₛ and loss tangent of dielectric materials tan (δ) as

$$C = \frac{tan ( δ )}{{R}_{s} ω} \qquad ( 1 )$$

respectively. That is, if changing the Rₛ, tan (δ) for different materials or ω, the C becomes a variable capacitance.

### Cauchy-Riemann Theorem

Referring to the [43], [12], [41] and [4], the complex variable analysis is a fundamental mathematical tool for the electrical circuit theory. In general, the impedance function consists of the real and imaginary parts. For each part of impedance functions, they are satisfied the Cauchy-Riemann Theorem. Let a complex function be

z(x,y)=F(x,y)+iG(x,y) (2)

where F(x, y) and G(x, y) are analytic functions in a domain D and the Cauchy-Riemann theorem is the first-order derivative of functions F(x, y) and G(x, y) with respect to x and y becomes

$$\begin{matrix}\frac{\partial F}{\partial x} = \frac{\partial G}{\partial y} & ( 3 ) \\ and & \\ \frac{\partial F}{\partial y} = - \frac{\partial G}{\partial x} & ( 4 )\end{matrix}$$

Furthermore, taking the second-order derivative with respect to x and y, we can obtain two 2^{nd}-order partial differential equations as

$$\begin{matrix}\frac{{\partial }^{2} F}{\partial {x}^{2}} + \frac{{\partial }^{2} F}{\partial {y}^{2}} = 0 & ( 5 ) \\ and & \\ \frac{{\partial }^{2} G}{\partial {x}^{2}} + \frac{{\partial }^{2} G}{\partial {y}^{2}} = 0 & ( 6 )\end{matrix}$$

respectively, also F(x, y) and G(x, y) are called the harmonic functions.

From the equation (2), the total derivative of the complex function z(x, y) is

$$dz ( x , y ) = ( \frac{\partial F}{\partial x} dx + \frac{\partial F}{\partial y} dy ) + i ( \frac{\partial G}{\partial x} dx + \frac{\partial G}{\partial y} dy ) \qquad ( 7 )$$

and substituting equations (3) and (4) into the form of (7), then the total derivative of the complex function (2) is dependent on the real function F(x, y) or in terms of the real-valued function F(x, y) (real part) only,

$$dz ( x , y ) = ( \frac{\partial F}{\partial x} dx + \frac{\partial F}{\partial y} dy ) + i ( \frac{\partial F}{\partial x} dx + \frac{\partial F}{\partial y} dx ) \qquad ( 8 )$$

and in terms of a real-valued function G(x, y) (imaginary part) only,

$$dz ( x , y ) = ( \frac{\partial G}{\partial x} dx + \frac{\partial G}{\partial y} dy ) + i ( \frac{\partial G}{\partial x} dx + \frac{\partial G}{\partial y} dy ) \qquad ( 9 )$$

There are the more crucial facts behind the (8) and (9) potentially. As a result, the total derivative of the complex function (7) depends on the real (imaginary) part of (2) function F(x, y) or G(x, y) only and never be a constant value function. One said, if changing the function of real part, the imaginary part function is also varied and determined by the real part via the equations (3) and (4). Since the functions F(x, y) and G(x, y) have to satisfy the equations (5) and (6), they are harmonic functions and then produce the frequency related elements discussed at the analytic continuation section. Moreover, the functions of real and imaginary parts are not entirely independent, referred to the Hilbert transforms in the textbooks [18, Page 296] and [20, Page 5 and Appendix One].

### Analytic Continuation

The impedance of the circuit has been discussed in this section. According to the equation (11) has shown that a PDR and NDR coupled in series in a circuit can induce significant, enlarged harmonic, sub-harmonic, super-harmonic and intermediate harmonic components which will modulate all together to present multi-band waveforms with broad bandwidth.

For each analytic function F(z) in the domain D, the Laurent series expansion of F(z) is defined as the following

$$\begin{matrix}F ( z ) = {\sum }_{n = - ∞}^{∞} {{a}_{n} ( z - {z}_{0} )}^{n} \\ = … + {{a}_{- 2} ( z - {z}_{0} )}^{- 2} + {{a}_{- 1} ( z - {z}_{0} )}^{- 1} + {a}_{0} + …\end{matrix} \qquad ( 10 )$$

where the expansion center z₀ is arbitrarily selected. Since this domain D for this analytic function F(z), any regular point imparts a center of a Laurent series [43, Page 223], i.e.,

$$F ( z ) = {\sum }_{- ∞}^{∞} {{c}_{n} ( z - {z}_{j} )}^{n}$$

where zⱼ is an arbitrary regular point in this complex analytic domain D for j=0, 1, 2, 3, . . . . For each index j, the complex variable is the product of its norm and phase,

$$z - {z}_{j} = \vert z - {z}_{j} \vert {e}^{{iθ}_{j}} and F ( z ) = {\sum }_{- ∞}^{∞} {c}_{n} {\vert z - {z}_{j} \vert}^{n} {e}^{i n {ω}_{j} t} \qquad ( 11 )$$

As long as a loop is formed the impedance function can be written in the form as the equation above. For each phase angle θⱼ, the corresponding frequency elements are naturally produced, say harmonic frequency ωⱼ. For different zⱼ correspond to the impedances with different values, frequencies and phases. Now we have the following results:
1. As the current passing through any smoothing conductor (without singularities), the frequencies are induced in nature.
2. This conductor imparts an order-Do resonant coupler.
3. This conductor is to be as an antenna without any bandwidth limitation.
4. Dynamic impedance matched.

### Positive and Negative Differential Resistances (PDR, NDR)

More inventively, due to observing the positive and negative differential resistors properties qualitatively, we introduce the Cauchy-Riemann equations, [27, Part 1, 2], [43], [12], [41] and [4], for describing a system impedance transient behaviors and particularly in some sophisticated characteristics system parametrization by one dedicated parameter ω. Consider the impedance z in specific variables (i, v) complex form of

z=F(i,v)+jG(i,v) (12)

where i, v are current and voltage respectively. Assumed that the functions F(i, v) and G(i, v) are analytic in the specific domain. From the Cauchy-Riemann equations (3) and (4) becomes as following

$$\begin{matrix}\frac{\partial F}{\partial i} = \frac{\partial G}{\partial v} & ( 13 ) \\ and & \\ \frac{\partial F}{\partial v} = - \frac{\partial G}{\partial i} & ( 14 )\end{matrix}$$

where in these two functions there exists one relationship based on the Hilbert transforms [18, Page 296] and [20, Page 5]. In other words, the functions F(i, v) and G(i, v) do not be obtained individually. Using the chain rule, equations (13) and (14) are further obtained

$$\begin{matrix}\frac{\partial F}{\partial ω} \frac{d ω}{d i} = \frac{\partial G}{\partial ω} \frac{d ω}{d v} & ( 15 ) \\ and & \\ \frac{\partial F}{\partial ω} \frac{d ω}{d v} = - \frac{\partial G}{\partial ω} \frac{d ω}{d i} & ( 16 )\end{matrix}$$

where the parameter ω could be the temperature field T, magnetic field flux intensity B, optical field intensity I, in the electric field for examples, voltage v, current i, frequency ω or electrical power P, in the mechanical field for instance, magnitude of force F, and so on. Let the terms

$$\begin{matrix}\{ \begin{matrix}\frac{d ω}{d v} > 0 \\ \frac{d ω}{d i} > 0\end{matrix} & ( 17 ) \\ or & \\ \{ \begin{matrix}\frac{d ω}{d v} < 0 \\ \frac{d ω}{d i} < 0\end{matrix} & ( 18 )\end{matrix}$$

be non-zero and the same sign. Under the same sign conditions as equation (17) or (18), from equation (15) to equation (16),

$$\begin{matrix}\frac{\partial F}{\partial ω} > 0 & ( 19 ) \\ \frac{\partial F}{\partial ω} < 0 & ( 20 ) \\ and & \\ \frac{\partial F}{\partial ω} = 0 & ( 21 )\end{matrix}$$

should be held simultaneously, where (21) means a constant resistor. From the viewpoint of making a power source, the simple way to perform equations (17) and (18) is to use the pulse-width modulation (PWM) method.

The further meaning of (17) and (18) is that using the variable frequency ω in pulse-width modulation to current and voltage is the most straightforward way, i.e.,

$$\{ \begin{matrix}\frac{\partial ω}{\partial v} \neq 0 \\ \frac{\partial ω}{\partial i} \neq 0\end{matrix} \qquad ( 22 )$$

In nature, ∂F/∂ω and ∂G/∂ω are positive or in general, under the condition like as the (23)

$$\frac{\partial F}{\partial ω} \frac{\partial G}{\partial ω} > 0 \qquad ( 23 )$$

in equation (17) or (18), we can obtain the result of

$$\frac{\partial ω}{\partial v} \frac{\partial ω}{\partial i} < 0 \qquad ( 24 )$$

In the report [40], we can find a negative slope in the I-V curve of some special fiber-carbon materials

$$\frac{d V}{d I} = - R$$

or in parameter form

$$\frac{\frac{d V}{d ω}}{\frac{d I}{d ω}} = - R$$

where the resistance R is a positive value,

$$R > 0$$

$$or$$

$$\frac{d V}{d ω} \frac{d I}{d ω} < 0$$

also its equivalent form

$$\frac{d ω}{d V} \frac{d ω}{d I} < 0$$

The negative sign contributed from the current or voltage has a backward direction with respect to input current I or voltage V. In particular, this reverse current (−I) is to be called “backflow.” After obtaining the qualitative behaviors of equation (19) and equation (20), also we need to further respectively define the quantitative behaviors of equation (19) and equation (20). Intuitively, any complete system described by the equation (12) could be analogy to the simple-parallel oscillator as FIG. 1 or simple-series oscillator as FIG. 2 which corresponds to 2^{nd}-order differential equation respectively either as (27) or (32). Referring to [42, Vol 2, Chapter 8, 9, 10, 11, 22, 23], [17, Page 173], [6, Page 181], [22, Chapter 10] and [14, Page 951-968], as the FIG. 1, let the current i₁ and voltage v_{C} be replaced by x, y respectively. From the Kirchhoff's Law, this simple oscillator is expressed as the form of

$$\begin{matrix}L \frac{d x}{d t} = y & ( 25 ) \\ C \frac{d y}{d t} = - x + {F}_{p} ( y ) & ( 26 )\end{matrix}$$

or in matrix form

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}0 \\ \frac{{F}_{p} ( y )}{C}\end{matrix} ] \qquad ( 27 )$$

where the function Fₚ(y) represents the generalized Ohm's law and for the single variable case, Fₚ(x) is the real part functin of the impedance function equation (12), the “p” in short, is a “parallel” oscillator. Furthermore, equation (27) is a Liénard system. The quality factor Qₚ is defined as

$${Q}_{p} ≡ \frac{1}{2 {ξ}_{p}} = \frac{{ω}_{pn} {f}_{p} ( y )}{L} \qquad ( 28 )$$

where ξₚ is the damping ration of (27),

$${ω}_{pn} = \frac{1}{\sqrt{LC}} \qquad ( 29 )$$

is the natural frequency of (27) and

$${f}_{p} ( y ) ≡ \frac{d {F}_{p} ( y )}{d y} {\vert}_{y}$$

respectively. If taking the linear from of Fₚ(y),

Fₚ(y)=Ky

and K>0, it is a normally linear Ohm's law. Also, the states equation of a simple series oscillator in the FIG. 2 is

$$\begin{matrix}L \frac{d x}{d t} = y - {F}_{s} ( x ) & ( 30 ) \\ C \frac{d y}{d t} = - x & ( 31 )\end{matrix}$$

in the matrix form,

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}- \frac{{F}_{s} ( x )}{L} \\ 0\end{matrix} ] \qquad ( 32 )$$

The i_{C}, vₗ have to be replaced by x, y respectively. The function Fₛ(x) indicates the generalized Ohm's law and (32) is the Liénard system too. The corresponding Q_{S} value is

$$\begin{matrix}{Q}_{s} = \frac{{ω}_{sn} L}{{f}_{s} ( x )} \\ where & ( 33 ) \\ {ω}_{sn} = \frac{1}{\sqrt{LC}} & ( 34 )\end{matrix}$$

is the natural frequency of (32) and

$${f}_{s} ( x ) ≡ \frac{d {F}_{s} ( x )}{d x} {\vert}_{x}$$

respectively. Again, considering one system as the FIG. 2, let L, C be to one, then the system (32) becomes the form of

$$[ \begin{matrix}\frac{d x}{d t} \\ \frac{d y}{d t}\end{matrix} ] = [ \begin{matrix}y - {F}_{s} ( x ) \\ - x\end{matrix} ] \qquad ( 35 )$$

To obtain the equilibrium point of the system (32), setting the right hand side of the system (35) is zero

$$\{ \begin{matrix}y - {F}_{s} ( 0 ) = 0 \\ - x = 0\end{matrix}$$

where Fₛ(0) is a value of the generalized Ohm's law at zero. The gradient of (35) is

$$[ \begin{matrix}- {F}_{s}^{′} ( 0 ) & 1 \\ - 1 & 0\end{matrix} ]$$

Let the slope of the generalized Ohm's law F′ₛ(0) be a new function as fₛ(0)

fₛ(0)=F′ₛ(0)

the correspondent eigenvalues λ_{1,2}^{s} are as

$${λ}_{1 , 2}^{s} = \frac{1}{2} [ - {f}_{s} ( 0 ) \pm \sqrt{{( {f}_{s} ( 0 ) )}^{2} - 4} ]$$

Similarly, in the simple parallel oscillator (27),

fₚ(0)=F′ₚ(0)

the equilibrium point of (27) is set to (Fₚ(0), 0) and the gradient of (27) is

$$[ \begin{matrix}0 & 1 \\ - 1 & {f}_{p} ( 0 )\end{matrix} ]$$

the correspondent eigenvalues λ_{1,2}^{p} are

$${λ}_{1 , 2}^{p} = \frac{1}{2} ( {f}_{p} \pm \sqrt{{( {f}_{p} ( 0 ) )}^{2} - 4} )$$

The qualitative properties of the systems (27) and (32), referred to [14] and [22], are as the following:
1. fₛ(0)>0, or fₚ(0)<0, its correspondent equilibrium point is a sink.
2. fₛ(0)<0, or fₚ(0)>0, its correspondent equilibrium point is a source.
Thus, observing previous sink and source quite different definitions, if the slope value of impedance function Fₛ(x) or Fₚ(y), fₛ(x) or fₚ(y) is a positive value

F′ₛ(x)=fₛ(x)>0 (36)

or

F′ₚ(y)=fₚ(y)>0 (37)
it is the name of the positive differential resistivity or PDR.
On contrary, it is a negative differential resistivity or NDR.

F′ₛ(x)=fₛ(x)<0 (38)

or

F′ₚ(y)=fₚ(y)<0 (39)
3. if fₛ(0)=0, or fₚ(0)=0, its correspondent equilibrium point is a bifurcation point, referred to [23, Page 433], [24, Page 26] and [22, Chapter 10] or fixed point, [2, Chapter 1, 3, 5, 6], or singularity point, [7], [1, Chapter 22, 23, 24].

F′ₛ(x)=fₛ(x)=0 (40)

or

F′ₚ(y)=fₚ(y)=0 (41)

Liénard Stabilized Systems

This section has used periodical motion to check a system's stability, and also has explained the role of PDR and NDR in a stable system.

Taking the system equation (27) or equation (32) is treated as a nonlinear dynamical system analysis, we can extend these systems to be a classical result on the uniqueness of the limit cycle, referred to [1, Chapter 22, 23, 24], [24, Page 402-407], [33, Page 253-260], [22, Chapter 10,11] and many articles [26], [19], [30], [28], [29], [16], [11], [39], [10], [15], [9], [13] for a dynamical system as the form of

$$\{ \begin{matrix}\frac{d x}{d t} = y - F ( x ) \\ \frac{d y}{d t} = - g ( x )\end{matrix} \qquad ( 42 )$$

under certain conditions on the functions F and g or its equivalent form of the nonlinear dynamics

$$\frac{{d}^{2} x}{d {t}^{2}} + f ( x ) \frac{d x}{d t} + g ( x ) = 0 \qquad ( 43 )$$

where the damping function f(x) is the first derivative of impedance function F(x) with respect to the state x

f(x)=F′(x) (44)

Based on the spectral decomposition theorem [23, Chapter 7], the damping function has to be a non-zero value if it is a stable system. The impedance function is a somehow specific pattern like as the FIG. 3,

y=F(x) (45)

From equation (42), equation (43) and equation (44), the impedance function F(x) is the integral of damping function f(x) over one specific operated domain x>0 as

F(x)=∫₀^{x}f(s)ds (46)

Under the assumptions that F, gεC¹(R), F and g are odd functions of x, F(0)=0, F′(0)<0, F has single positive zero at x=a, and F increases monotonically to infinity for x≧a as x→∞, it follows that the Liénard's system equation (42) has exactly one limit cycle and it is stable. Comparing the (46) to the bifurcation point defined in the section ( ) the initial condition of the (46) is extended to an arbitrary setting as

F(x)=∫ₐ^{x}f(ζ)dζ (47)

where aεR. Also, the FIG. 4 is modified as where the dashed lines are different initial conditions. Based on above proof and carefully observing the function (44) in the FIG. 4, we conclude the critical insights of the system (42). We conclude that an adaptive-dynamic damping function F(x) with the following properties:
1. The damping function is not a constant. At the interval,

α≦a
the impedance function F(x) is

F(x)<0
The function derivative of F(x) should be

F′(x)=f(x)≧0 (48)
which is a PDR as defined by (36) or (37) and

F′(x)=f(x)<0 (49)
which is a NDR as defined by (38) or (39), and both hold simultaneously. Which means that the impedance function F(x) has the negative and positive slopes at the interval α≦a.
2. Following the Liénard theorem [33, Page 253-260], [22, Chapter 10, 11], [24, Chapter 8] and the correspondent theorems, corollaries and lemma, we can further conclude that one stabilized system which has at least one limit cycle, all solutions of the system (42) converge to this limit cycle even asymptotically stable periodic closed orbit. In fact, this kind of system construction can be realized a stabilized system in Poincaré sense [33, Page 253-260], [22, Chapter 10, 11], [17, Chapter 1, 2, 3, 4], [6, Chapter 3].

Furthermore, one nonlinear dynamic system is as the following form of

$$\begin{matrix}\frac{{d}^{2} x}{d {t}^{2}} + ɛ f ( x , y ) \frac{d x}{d t} + g ( x ) = 0 \\ or & ( 50 ) \\ \{ \begin{matrix}\frac{d x}{d t} = y - ɛ F ( x , y ) \\ \frac{d y}{d t} = - g ( x )\end{matrix} \\ where & ( 51 ) \\ f ( x , y ) & ( 52 )\end{matrix}$$

is a nonzero and nonlinear damping function,

g(x) (53)

is a nonlinear spring function, and

F(x,y) (54)

is a nonlinear impedance function also they are differentiable. If the following conditions are valid
1. there exists a>0 such that f(x, y)>0 when \sqrt{x²+y²}≦a.
2. f(0,0)<0 (hence f(x, y)<0 in a neighborhood of the origin).
3. g(0)=0, g(x)>0 when x>0, and g(x)<0 when x<0.
4. G(x)=∫₀^{x}g(u)du→∞ as x→∞.
then (50) or (51) has at least one periodic solution.

### 0.1 Frequency-Shift Damping Effect

This section has used frequency shifting to re-define power generation and dissipation. This section also has revealed frequency shifting produced by a PDR and NDR coupled in series. Referring to the books [4, p 313], [35, Page 10-11], [25, Page 13] and [41, page 171-174], we assume that the function is a trigonometric Fouries series generated by a function g(t)εL(I), where g(t) should be bounded and the unbounded case in the book [41, page 171-174] has proved, and L(I) denotes Lebesgue-integrable on the interval I, then for each real β, we have

$${lim}_{ω \to ∞} {\int }_{I} g ( t ) {e}^{i ( ω t + β )} d t = 0 \\ where \\ {e}^{i ( ω t + β )} = cos ( ω t + β ) + i sin ( ω t + β ) \qquad ( 55 )$$

the imaginary part of (55)

$${lim}_{ω \to ∞} {\int }_{I} g ( t ) sin ( ω t + β ) d t = 0 \qquad ( 56 )$$

and real part of (55)

$${lim}_{ω \to ∞} {\int }_{I} g ( t ) cos ( ω t + β ) d t = 0 \qquad ( 57 )$$

are approached to zero as taking the limit operation to infinity, ω→∞, where equation (56) or (57) is called “Riemann-Lebesgue lemma” and the parameter ω is a positive real number. If g(t) is a bounded constant and ω>0, it is naturally the (56) can be further derived into

$$\vert {\int }_{a}^{b} {e}^{i ( ω t + β )} d t \vert = \vert \frac{{e}^{i a ω} - {e}^{i b ω}}{ω} \vert \leq \frac{2}{ω}$$

where [a, b]εI is the boundary condition and the result also holds if on the open interval (a, b). For an arbitrary positive real number ε>0, there exists a unit step function s(t), referred to [4, p 264], such that

$${\int }_{I} \vert g ( t ) - s ( t ) \vert d t < \frac{ɛ}{2}$$

Now there is a positive real number M such that if ω≧M,

$$\vert {\int }_{I} s ( t ) {e}^{i ( ω t + β )} d t \vert < \frac{ɛ}{2} \qquad ( 58 )$$

holds. Therefore, we have

$$\vert {\int }_{I} g ( t ) {e}^{i ( ω t + β )} d t \vert \leq \vert {\int }_{I} ( g ( t ) - s ( t ) ) {e}^{i ( ω t + β )} d t \vert + \vert {\int }_{I} s ( t ) {e}^{i ( ω t + β )} d t \vert \leq {\int }_{I} \vert g ( t ) - s ( t ) \vert d t + \frac{ɛ}{2} < \frac{ɛ}{2} + \frac{ɛ}{2} = ɛ \qquad ( 59 )$$

i.e., (56) or (57) is verified and hold.

According to the Riemann-Lebesgue lemma, the equation (55) or (57) and (56), as the frequency ω approaches to ∞ which means

$$ω ≫ 0 \\ then \\ {lim}_{ω \to ∞} {\int }_{I} g ( t ) {e}^{i ( ω t + β )} d t = 0 \qquad ( 60 )$$

The equation (60) is a foundation of the energy dissipation. For removing any destructive energy component, (60) tells us the truth whatever the frequencies are produced by the harmonic and subharmonic waveforms and completely “damped” out by the ultra-high frequency modulation.

Observing (60), the function g(t) is an amplitude of power which is the amplitude-frequency dependent and seen the book [24, Chapter 3, 4, 5, 6]. It means if the higher frequency ω produced, the more g(t) is attenuated. When moving the more higher frequency, the energy of (60) is the more rapidly diminished. We conclude that a large part of the power has been dissipated to the excited frequency ω fast drifting across the board of each reasonable resonant point, rather than transferred into the thermal energy (heat). After all, applying the energy to a system periodically causes the ω to be drifted continuously from low to very high frequencies for the energy absorbing and dissipating. Again removing the energy, the frequency rapidly returns to the nominal state. It is a fast recovery feature. That is, this system can be performed and quickly returned to the initial states periodically.

As the previous described, realized that the behavior of the frequency getting high as increasing the amplitude of energy and vice versa, expressed as the form of

ω=ω(g(t)) (61)

The amplitude-frequency relationship as (61) which induces the adaptation of system. It means which magnitude of the energy produces the corresponding frequency excitation like as a complex damper function (52).

Consider one typical example, assumed that given the voltage

v(t)=V₀e^{j(ω}^{ᵥ}^{t+α}^{ᵥ}⁾ (62)

and current

i(t)=I₀e^{j(ω}^{ᵢ}^{t+α}^{ᵢ}⁾ (63)

the total applied power is defined as

$$\begin{matrix}P = {\int }_{0}^{T} i ( t ) v ( t ) d t \\ = \frac{{V}_{0} {I}_{0}}{( {ω}_{v} + {ω}_{i} )} ( {e}^{j ( {α}_{v} + {α}_{i} + \frac{π}{2} )} ( 1 - {e}^{j ( {ω}_{v} + {ω}_{i} ) T} ) )\end{matrix} \qquad \begin{matrix}( 64 ) \\ \\ ( 65 )\end{matrix}$$

Let the frequency ω and phase angle β be as

ω=ωᵥ+ωᵢ

and

β=αᵢ+αᵥ

then equation (65) becomes into the complex form of

$$\begin{matrix}P = π ( ω , β , T ) + j Q ( ω , β , T ) \\ = \frac{{V}_{0} {I}_{0}}{ω} ( {e}^{j ( β + \frac{π}{2} )} ( 1 - {e}^{jω T} ) )\end{matrix} \qquad \begin{matrix}( 66 ) \\ ( 67 )\end{matrix}$$

where real power π (ω, β, T) is

$$π ( ω , β , T ) = \frac{2 {V}_{0} {I}_{0} sin ( ω T ) cos ( 2 π - 2 β - ω T )}{ω} \qquad ( 68 )$$

and virtual power Q (ω, β, T) is

$$Q ( ω , β , T ) = \frac{2 {V}_{0} {I}_{0} sin ( ω T ) sin ( 2 π - 2 β - ω T )}{ω} \qquad ( 69 )$$

respectively. Observing (55), taking limit operation to (66), (65) or (67)

$${lim}_{ω \to ∞} \frac{{V}_{0} {I}_{0}}{ω} ( {e}^{j ( β + \frac{π}{2} )} ( 1 - {e}^{jω T} ) ) = 0 \qquad ( 70 )$$

the electric power P is able to filter out completely no matter how they are real power (68) or virtual power (69) via performing frequency-shift or Doppler's shift operation, where ωᵥ, ωᵢ are frequencies of the voltage v(t) and current i(t), and αᵥ, αᵢ are correspondent phase angles and T is operating period respectively.

Let the real power to be zero,

$$2 π - 2 β - ω T = \frac{π}{2}$$

which means that the frequency ω is shifted to

$${ω}_{Vir} = \frac{1}{T} ( \frac{3 π}{2} - 2 β )$$

The total power (66) is converted to the maximized virtual power

$$\begin{matrix}Max ( Q ( {ω}_{Vir} , β , T ) ) = \frac{2 {V}_{0} {I}_{0} sin ( {ω}_{Vir} T )}{{ω}_{Vir}} \\ = \frac{2 {V}_{0} {I}_{0} T cos ( 2 β )}{( \frac{3 π}{2} - 2 β )}\end{matrix}$$

Similarly,

$$2 π - 2 β - ω T = 0$$

$$or$$

$${ω}_{Re} = \frac{2}{T} ( π - β )$$

the total power (66) is totally converted to the maximized real power

$$\begin{matrix}Max ( π ( {ω}_{Re} , β , T ) ) = \frac{2 {V}_{0} {I}_{0} sin ( {ω}_{Re} T )}{{ω}_{Re}} \\ = \frac{{V}_{0} {I}_{0} T sin ( 2 β )}{( β - π )}\end{matrix}$$

In fact, moving out the frequency element ω as the (70) is power conversion between real power (68) and virtual power (69).

### Maximized Power Transfer Theorem

Consider the voltage source vₛ to be

V_{S}=V₀

and its correspondent impedance zₛ

Zₛ=Rₛ+jQₛ

The impedance of the system load Z_{L} is

Z_{L}=R_{L}+jQ_{L}

The maximized power transmission occurrence if R_{L} and Q_{L} are varied, not to be the constants,

R_{L}=Rₛ (71)

where the resistor Rₛ is called equivalent series resistance or ESR and

Q_{L}=−Qₛ (72)

Comparing (71) to (72), the impedances of voltage source and the system load should be conjugated, i.e.,

Z_{L}=Zₛ*

then the overall impedance becomes the sum of Zₛ+Z_{L}, or

$$\begin{matrix}Z = {Z}_{s} + {Z}_{L} \\ = {R}_{s} + {R}_{L} + j ( {Q}_{s} + {Q}_{L} )\end{matrix} \qquad ( 73 )$$

The power of impedance consumption is

$$\begin{matrix}P = {I}^{2} {R}_{L} \\ = {( \frac{[ ( {R}_{s} + {R}_{L} ) - j ( {Q}_{s} + {Q}_{L} ) ]}{{( {R}_{s} + {R}_{L} )}^{2} + {( {Q}_{s} + {Q}_{L} )}^{2}} )}^{2} {V}_{0}^{2} {R}_{L}\end{matrix}$$

Let the imaginary part of P be setting to zero,

(Qₛ+Q_{L})=0 (74)

i.e.,

Qₛ=−Q_{L}

or resonance mode. In fact, it is an impedance matched motion. The power of the total impedance consumption becomes just real part only,

$$P = \frac{{V}_{0}^{2} {R}_{L}}{{( {R}_{s} + {R}_{L} )}^{2}}$$

From the basic algebra,

$$\frac{{R}_{s} + {R}_{L}}{2} \geq \sqrt{{R}_{s} {R}_{L}}$$

where Rₛ and R_{L} have to be the positive values,

Rₛ,R_{L}≧0 (75)

or

(Rₛ−R_{L})²=0

In other words, the resistance Rₛ and R_{L} are the same magnitudes as

Rₛ=R_{L} (76)

The power of impedance consumption P becomes an averaged power Pₐᵥ

$$\begin{matrix}{P}_{av} = \frac{1}{2} \frac{{V}_{0}^{2}}{{R}_{L}} \\ = \frac{{V}_{0}^{2}}{( 2 {R}_{L} )}\end{matrix} \qquad ( 77 )$$

and the total impedance becomes twice of the resistance R_{L} or Rₛ.

Z=2R_{L} (78)

Let (72) be a zero, i.e., impedance matched,

Qₛ=Q_{L}=0 (79)

from (76), the total impedance and consumed power P are (78), (77) respectively. In other word, comparing the (2) to (79), it is hard to implement that the imaginary part of impedance (73) keeps zero. But applying the (3) and (4) operations into the form of (7), the results have been verified on the Cauchy-Riemann theorem, also it is a possible way to create the zero value of imaginary part of total impedance (73) or (7). Another way is producing a conjugated part of (73) or (7) dynamically and adaptively or order-∞ resonance mode.

### REFERENCES

[1] Nicholas Minorsky. Nonlinear oscillations. Van Nostrand, N.Y., http://www.alibris.com, 1962.
[2] Alberto Abbondandolo. Morse Theory for Hamiltonian Systems. CRC Press., http://www.crcpress.com/, 2000.
[3] D. K. Anand. An Introduction to Control Systems. Pergamon Press., http://www.amazon.com/, 1974.
[4] Tom M. Apostol. Mathematical Analysis. Addison-Wesley Publishing Company., http://www.aw-bc.com/, 2nd edition, 1975.
[5] V. I. Arnold. Ordinary Differential Equations. MIT Press., http://www.mitpress.com/, 1973.
[6] V. I. Arnold. Geometrical Methods in the Theory of Ordinary Differential Equations. Springer-Verlag., http://www.springer-ny.com/, 2nd edition, 1988.
[7] V. I. Arnold. Theory of Singularities and its Applicatoins., volume 1. American Mathematicial Society., http://www.ams.org/, 2nd edition, 1990.
[8] Donald R. Askeland. The Science and Engineering of Materials. PWS Publishers., alternate edition, 1985.
[9] J. Balakrishnan. A geometric framework for phase synchronization in coupled noisy nonlinear systems. Physical Review E, 73:036206, 2006.
[10] Timoteo Carletti and Gabriele Villari. A note on existence and uniqueness of limit cycles for li'enard systems, 2003.
[11] V. K. Chandrasekar, M. Senthilvelan, and M. Lakshmanan. An unusual li'enard type nonlinear oscillator with properties of a linear harmonic oscillator, 2004.
[12] E. T. Copson. An introduction to the theory of functions of a complex variable. Oxford University Press., http://www.amazon.com/, 4th edition, 1948.
[13] M. C. Cross, A. Zumdieck, Ron Lifshitz, and J. L. Rogers. Synchronization by nonlinear frequency pulling. Physical Review Letters, 93:224101, 2004.
[14] R. Wong F. Cuker. The Collected Papers of Stephen Smale., volume 3. Singapore University Press., http://www.worldscibooks.com/mathematics, 2000.
[15] H. Giacomini and S. Neukirch. On the number of limit cycles of the lienard equation, 1997.
[16] Jaume Gine and Maite Grau. A note on “relaxation oscillators with exact limit cycles”, 2005.
[17] John Guckenheimer and Philip Holmes. Nonlinear Oscillations, Dynamical Systems, and Bifurcations of Vector Fields. Springer-Verlag., http://www.springer-ny.com/, 1997.
[18] Ernest A. Guillemin, editor. Synthesis of Passive Networks: Theory and Methods Appropriate to the Realization and Approximation Problems. John Wiley and Sons., 1957.
[19] Edward H. Hellen and Matthew J. Lanctot. Nonlinear damping of the lc circuit using anti-parallel diodes, 2006.
[20] Arthur R. Von Hippel. Dielectrics and Waves. A John Wiley & Sun, Inc., http://www.wiley.com, 1954.
[21] Arthur Von Hippel. Dielectric Materials and Applications. Artech House Publishers., http://www.artechhouse.com, 1995.
[22] Morris W. Hirsh and Stephen Smale. Differential Equations, Dynamical Systems and Linear Algebra. Academic Press., http://www.academicpress.com/, 1974.
[23] Thomas J. R. Hughes. Jerrold E. Marsden. Mathematical Foundations of Elasticity. Prentice-Hall, Inc., http://www.doverpublications.com/, 1984.
[24] D. W. Jordan and Peter Smith. Nonlinear Ordinary Differential Equations. Oxford University Press., http://www.oup.co.uk/academic/, 3rd edition, 1999.
[25] Yitzhak Katznelson. An Introduction to Harmonic Analysis. Cambridge University Press, http://www.amazon.com/, 2nd edition, 1968.
[26] Alexandra S. Landsman and Ira B. Schwartz. Predictions of ultra-harmonic oscillations in coupled arrays of limit cycle oscillators, 2006.
[27] Serge Lang. Complex Analysis. Springer-Verlag., http://www.springer.de/phy/books/ssp, 4th edition, 1999.
[28] Jose-Luis Lopez and Ricardo Lopez-Ruiz. The limit cycles of lienard equations in the strongly non-linear regime, 2002.
[29] Jose-Luis Lopez and Ricardo Lopez-Ruiz. Approximating the amplitude and form of limit cycles in the weakly non-linear regime of lienard systems, 2006.
[30] Jose-Luis Lopez and Ricardo Lopez-Ruiz. The limit cycles of lienard equations in the weakly nonlinear regime, 2006.
[31] A. J. Moulson and J. M. Herbert. Electroceramics: Materials, Properties, Applications. Wiley and Sun Ltd., http://www3.wileye.com, 2nd edition, 2003.
[32] Peter J. Olver. Applications of Lie Groups to Differential Equations. Springer-Verlag., http://www.springer-ny.com/, 1993.
[33] Lawrence Perko. Differential Equations and Dynamical Systems. Springer-Verlag, New York, Inc., http://www.springer-ny.com, 3rd edition, 2000.
[34] Jerrold E. Marsden. Ralph Abraham. Foundations of Mechanics. Perseus Publishing., http://www.perseusbooksgroup.com/front.html, 2nd edition, 1984.
[35] Michael Reed and Barry Simon. Methods of Modern Mathematical Physics: Fourier Analysis, Self-Adjointness., volume 2. Academic Press., http://www.academicpress.com, 1975.
[36] Michael Reed and Barry Simon. Methods of Modern Mathematical Physics: Analysis of Operators., volume 4. Academic Press., http://www.academicpress.com, 1978.
[37] Michael Reed and Barry Simon. Methods of Modern Mathematical Physics: Scattering Theory., volume 3. Academic Press., http://www.academicpress.com, 1979.
[38] George F. Simmons. Introduction to Topology and Modern Analysis. McGRAW-HILL Inc., http://books.mcgraw-hill.com, 1963.
[39] Ali Taghavi. On periodic solutions of lienard equations, 2004.
[40] Shoukai Wang and D. D. L. Chung. Apparent negative electrical resistance in carbon fiber composites, 1999.
[41] E. T. Whittaker and G. N. Watson. A Course of Modern Analysis. Cambridge Mathematical Library., http://www.cambridge.org, 4th edition, 1927.
[42] Matthew Sands. WRichard P. Feynman, Robert B. Leighton. Feynman Lectures On Physics: The Complete And Definitive Issue., volume 3. Addison Wesley Publishing Company., http://www.aw-bc.com, 2nd edition, 1964.
[43] A. David Wunsch. Complex Variables with Applications. Addison-Wesley Publishing Company Inc., http://www.aw-bc.com/, 1983.

### 1 SUMMARY OF THE INVENTION

The first objective is to provide a backward current decoupler which can decouple backward current from forward current.

The second objective of the invention is to provide a new p-n junction device which has built-in damper and better capacitive property which consumes less power.

The third objective of the invention is to provide a new sensor which can be interactable with thermal, magnetic, optical, force or electrical fields.

### 2 BRIEF DESCRIPTION OF THE FIGURES

FIG. 1 has shown a parallel oscillator;

FIG. 2 has shown a serial oscillator;

FIG. 3 has shown the function F(x) and a trajectory Γ of Liénard system;

FIG. 4 has shown the impedance function F(x) is independent of the initial condition setting;

FIG. 5 a capacitor C decomposed into an ideal capacitor Cᵢ, a series parasitic resistor Rₛ;

FIG. 6a has defined a symbol of a backward current decoupler;

FIG. 6b has shown a two-lamina composite in top view;

FIG. 6c has shown the two-lamina composite of FIG. 6b in side view;

FIG. 6d has shown a multi-lamina composite in side view;

FIG. 6e has shown the multi-lamina composite of FIG. 6d in top view;

FIG. 6f has shown a PNDR junction formed by two fibers;

FIG. 6g has shown a PNDR junction formed by two fibers;

FIG. 6h has shown a PPNDR junction formed by two fibers;

FIG. 6i has shown a three-layer thin films;

FIG. 6j has shown the three-layer thin films of FIG. 6i rolled into a shape of a fiber;

FIG. 6l has shown two loops formed in the two-lamina composite;

FIG. 6m has shown a capacitor matrix in side view;

FIG. 6n has shown the capacitor matrix of FIG. 6m in top view;

FIG. 6o has shown a six-lamina composite in side view;

FIG. 6p has shown the six-lamina composite of FIG. 6o in top view;

FIG. 6q has shown a 3×3 sensor matrix; and

FIG. 6r has shown a PPNDR junction formed by two fibers.

### 3 DETAILED DESCRIPTION

A device with its resistance irrelevant to frequency, which is described by equations (21), (40) and (41), can be called pure resistor in the present invention.

The three equations (21), (19) and (20) should hold simultaneously. A damper contains three devices respectively described by the equations (48), (49) and (40) and (41) as PDR device, NDR device and pure resistor electrically connected in series. Because the pure resistor exists in almost all the devices so that a damper can be practically reliazed by a PDR device and a NDR device electrically connected in series with each other.

According to equations (19) and (20), the impedance functions of the PDR and NDR devices can vary with the parameter ω, which can be temperature field T, magnetic field flux intensity B, optical field intensity I, electrical field such as voltage v, current i, frequency f or electrical power P, mechanical field such as magnitude of force F, vibration force, and so on, or any combination of them listed above.

A device has a first input terminal, a first output terminal, a second input terminal and a second output terminal. If an input current or an input forward current flows through the device through a pair of its first input and first output terminals, and a backward current, which is induced in the device by the input and is opposite to the input forward current in the device, flows through a pair of its second input and the second output terminals then the device is called a backward current decoupler.

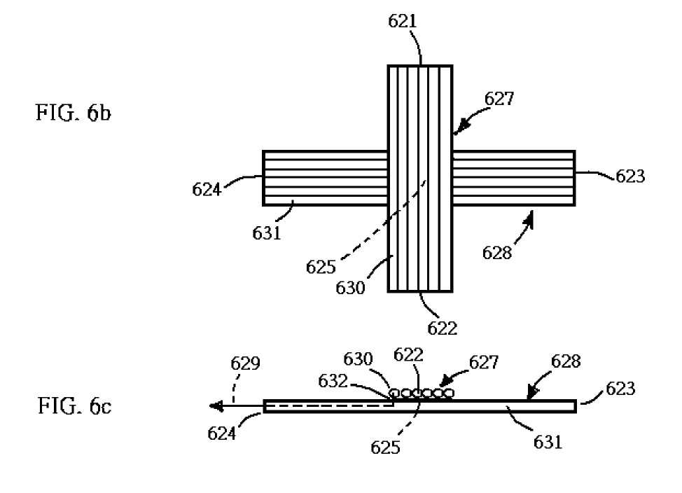

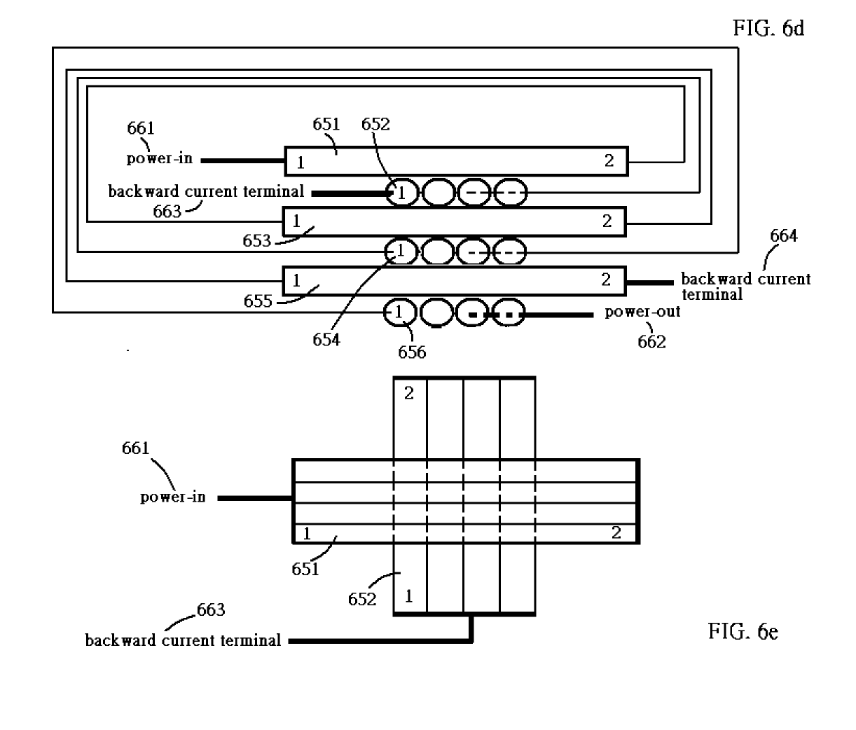

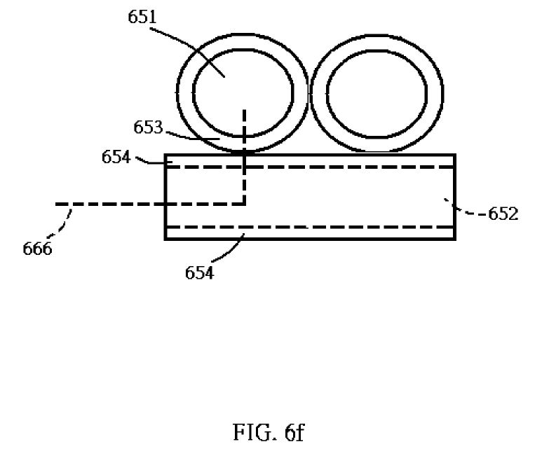

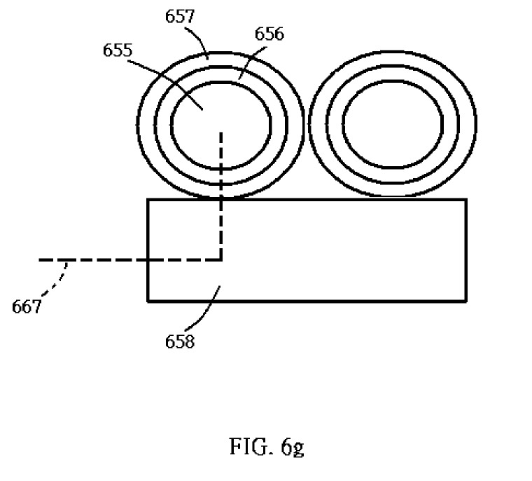

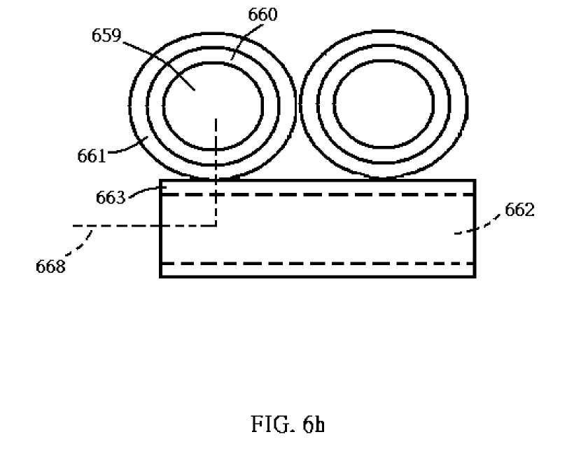

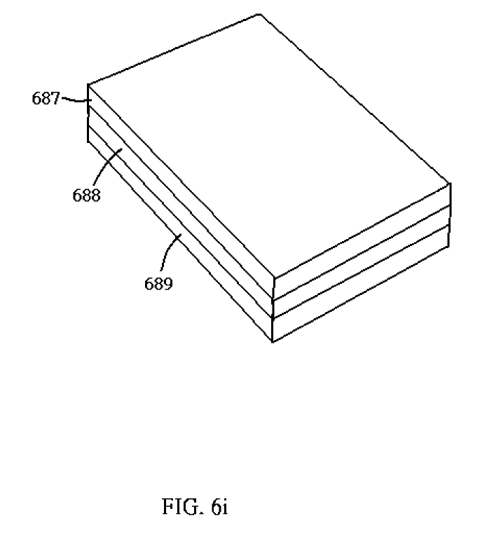

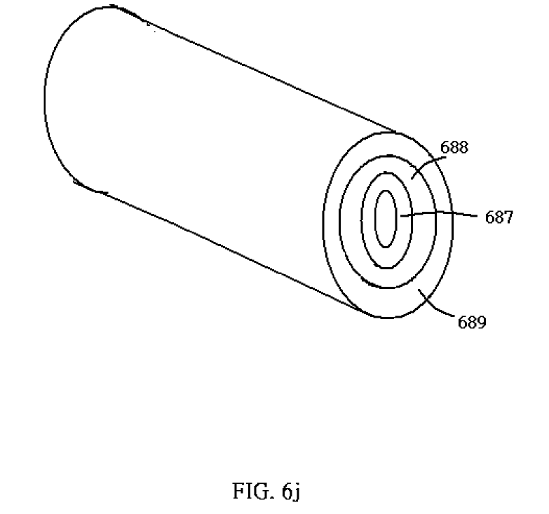

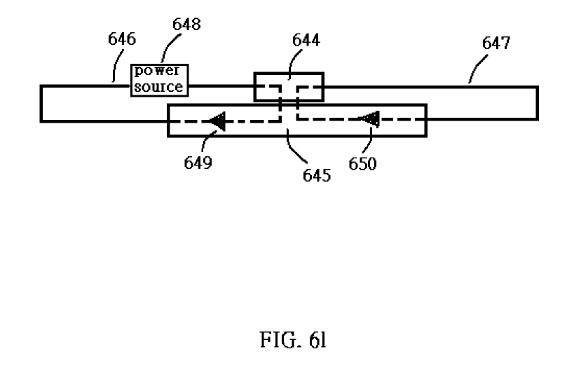

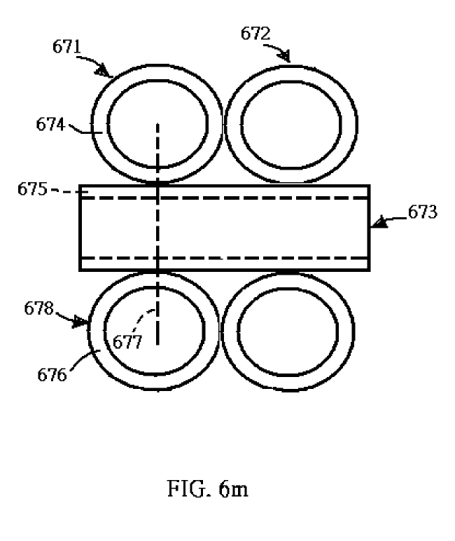

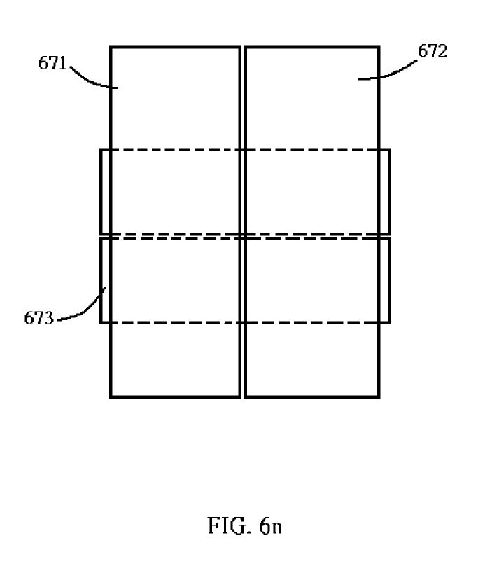

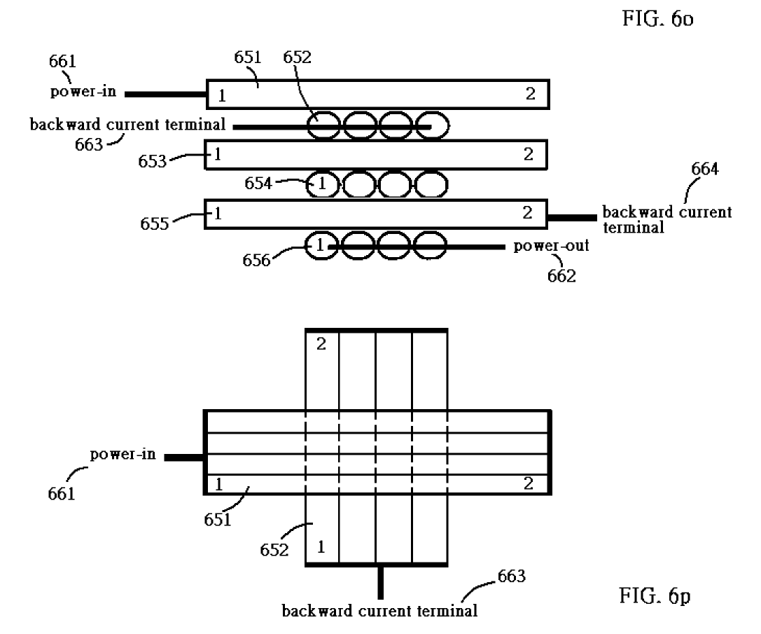

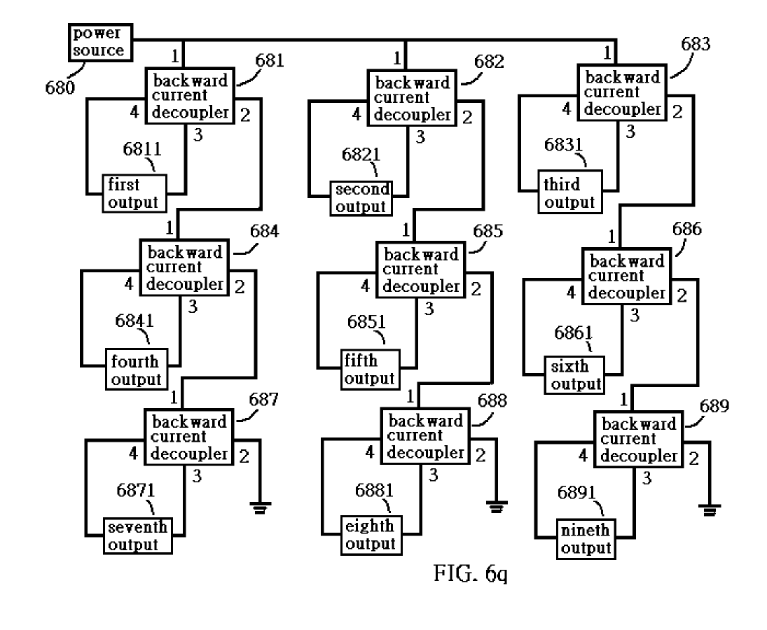

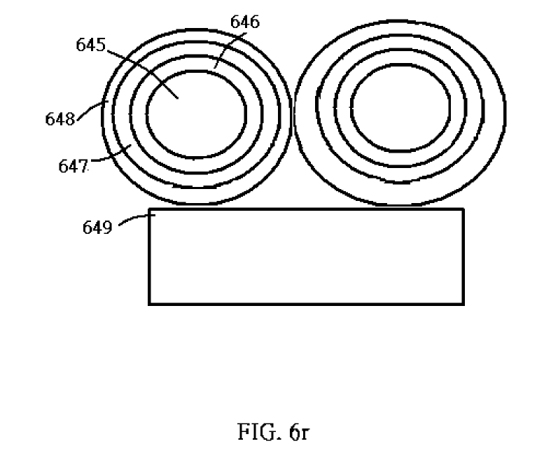

Using a drawing to make the definition more understood, FIG. 6a has shown a backward current decoupler 605 having a first terminal 601, a second terminal 602, a third terminal 603 and a fourth terminal 604. For example, a forward current flows through its first and second terminals 601, 602 and a backward current induced in the decoupler 605 by the input flows through the third and fourth terminals 603, 604.

A research about a carbon fiber composite was revealed in a Chung's report “apparent negative electrical resistance in carbon fiber composites” and experiments of building a two-lamina and multi-lamina crossply carbon fiber-matrix composites have been successfully conducted. For convenience, the Chung's report “apparent negative electrical resistance in carbon fiber composites” can also be called in short as “Chung's report” in the invention.

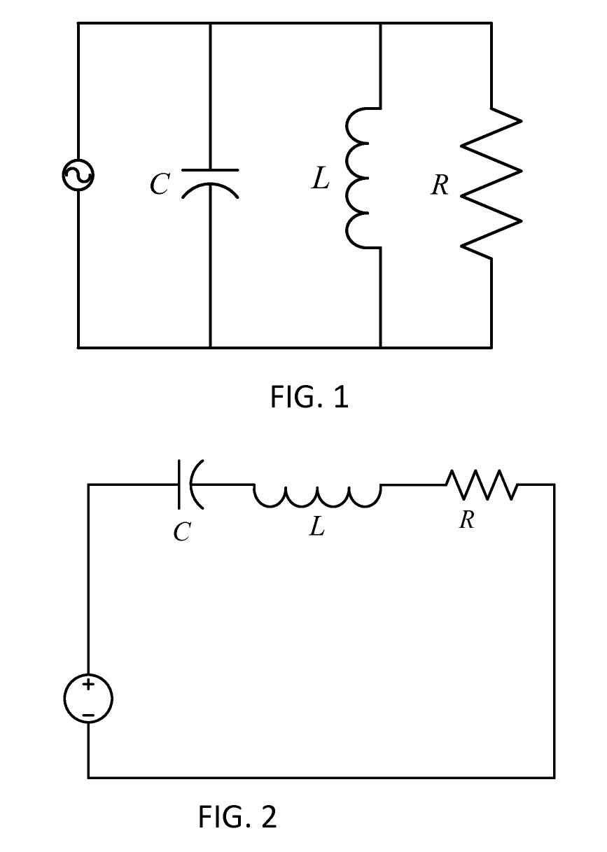

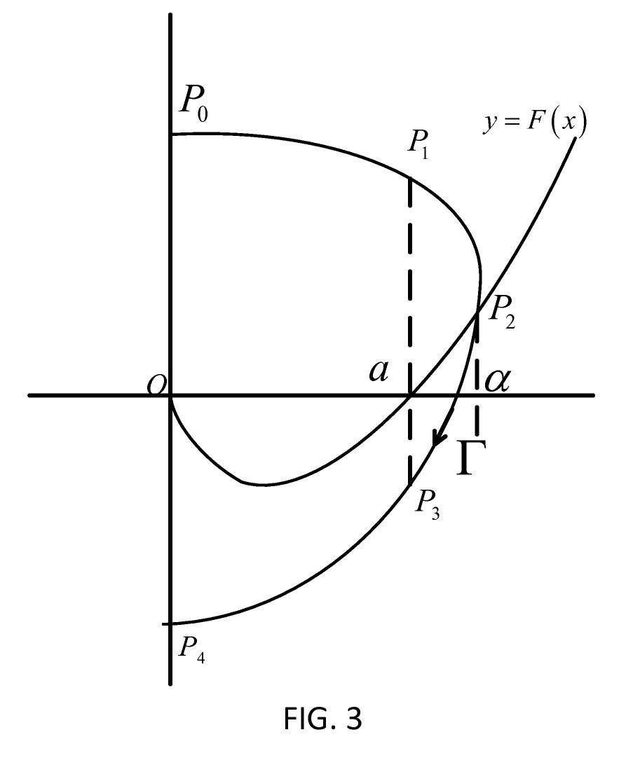

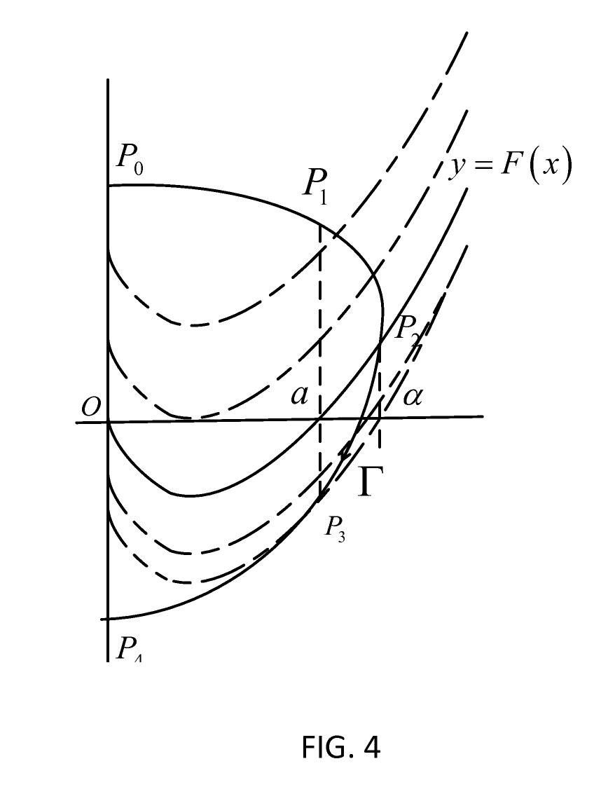

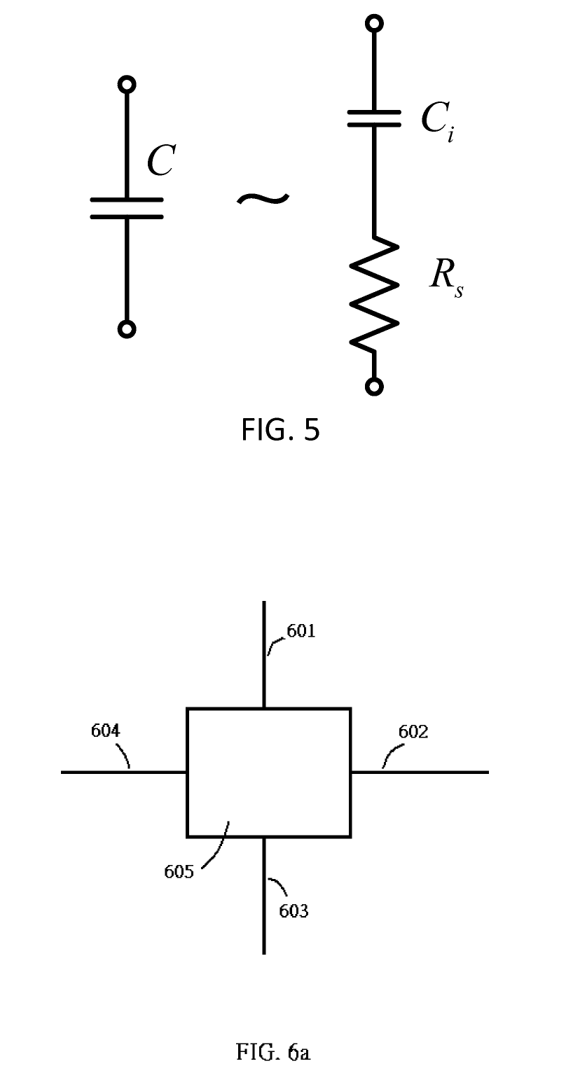

FIGS. 1, 2 and 4 in the report of “apparent negative electrical resistance in carbon fiber composites” have respectively shown a two-lamina crossply carbon fiber-matrix composite configuration, the experimental set-up for obtaining current-voltage characteristics and a negative slope shown in the current-voltage characteristics for the composite configuration cured at 1.4 MPa. The phenomenon of backward current was found in both the two-lamina and the multi-lamina crossply carbon fiber-matrix composite revealed in the same report. For simplicity, the two-lamina crossply carbon fiber-matrix composite and multi-lamina crossply carbon fiber-matrix composite in the Chung's report can also be respectively called in short as two-lamina and multi-lamina composites in the present invention.

FIGS. 6b and 6c have respectively repeated the two-lamina composite of the Chung's report in top and side views. The two-lamina composite has two laminae crossed with each other and each lamina has a plurality of carbon fibers (or fibers in short) paralleled one by one. The multi-lamina composite has more than two laminae and each lamina has a plurality of fibers paralleled one by one.

A first and second laminae 627, 628 of the two-lamina composite shown in FIGS. 6b and 6c are respectively formed by a plurality of fibers paralleled one by one, and each of the first lamina 627 and second laminae 628 has two ends respectively shown as 621, 622 and 623, 624. It's noticed that the plurality of the fibers at each end 621, 622, 623 and 624 are electrically connected together.

By using a fiber on each lamina to do the explanation, a first fiber of the first lamina can electrically contact with a second fiber of the second lamina so that a current can have chance to flow from the first fiber of the first lamina to the second fiber of the second lamina through a “junction” formed by the electrical contact of the two fibers. Using a first fiber 630 on the first lamina 627 and a second fiber 631 on the second lamina 628 shown in FIG. 6b, 6c as an example, current could flow from the first fiber 630 of the first lamina 627, through a junction 632 formed by the electrical contact of the two fibers 630, 631 and flow into the second fiber 631 of the second lamina 628. A line 629 has shown a possibility that a current could flow from the first fiber 630 of the first lamina 627 to the second fiber 631 of the second lamina 628 and out of the terminal 624 of the second lamina 628. Because there are a plurality of junctions formed between a plurality of fibers respectively on the two different laminae 627, 628 and a term “collective junction” 625 is used to express all the junctions formed by the coupling of the two laminae 627, 628.

The experiment of the two-lamina composite in the Chung's report has shown, if a forward current flows in a first terminal 621 of the first lamina 627, through the collective junction 625 and then flows out of a second terminal 623 of the second lamina 628 then a backward current is induced by the input in the two-lamina composite flowing through a pair of the other two terminals 622, 624 respectively on the different laminae. Obviously, the two-lamina composite is a four-terminal backward current decoupler.

Multi-lamina crossply carbon fiber-matrix composite (or multi-lamina composite in short) has more than two laminae. A multi-lamina composite has at least four terminals of which two terminals, power-in and power-out terminals, are for forward current loop, and the other two terminals, two backward current terminals, are for induced backward current loop. The power-in terminal and power-out terminal are on the different laminae, and, the two backward current terminals are on the different laminae.

A multi-lamina composite of Chung's report is simply repeated in FIGS. 6d and 6e, which have respectively demonstrated a 6-lamina composite respectively in side and top views and each lamina has four fibers and the multi-lamina composite has power-in terminal 661, power-out terminal 662, and two backward terminals 663, 664. The four fibers at each terminal are electrically connected together. Two opposite ends of each lamina are respectively marked by the numbers 1 and 2, which can be respectively called as end 1 and end 2. Shown in FIG. 6d, the top lamina is a first lamina and the lamina next below the top lamina is a second lamina and so on to the lowest lamina is a sixth lamina.

FIG. 6e has shown the top view of the 6-lamina composite of FIG. 6d of which a first fiber 651 of the first lamina, a second fiber 652 of the second lamina, a power-in terminal 661 on the first lamina and a backward current terminal 663 on the second lamina are seen. The side view of the 6-lamina composite shown in FIG. 6d has shown the power-in terminal 661 on the first lamina passes through six laminae to the power-out terminals 662 on the sixth laminae for forward current and induced backward current opposite to the forward current flows through the two backward current terminals 663, 664 respectively on the second and fifth laminae. It's obviously, the forward and backward currents flow through a plurality of collective junctions and laminae in the embodiment. All the ends other than the power-in terminal 661, power-out terminal 662, and two backward current terminals 663, 664 are interconnected jumping over adjacent lamina, for example, an end 2 of the first lamina connects with an end 1 of the third lamina and an end 2 of the third lamina connects with an end 1 of the fifth lamina and so on. The interconnections among the laminae shown in the embodiment of FIGS. 6d and 6e are not limited in the invention. FIGS. 6o and 6p have respectively shown the 6-lamina composite without no interconnections among laminae except the power-in 661, power-out 662, and two backward terminals 663 and 664.

The dotted lines appeared in the second, fourth and sixth laminae shown in FIG. 6d respectively express the electrical connection to the end 2 opposite to the end 1 on the same lamina. FIG. 6d has also shown a third fiber 653, a fourth fiber 654, a fifth fiber 655 and a sixth fiber 656 respectively on the third, fourth, fifth and sixth laminae.

Using only a fiber of each lamina to easier do the explanation, a forward current could flow into the first fiber 651 through the power in terminal 661 on the first lamina, through the second fiber 652 on the second lamina, the third fiber 653 on the third lamina, the fourth fiber 654 on the fourth lamina, the fifth fiber 655 on the fifth lamina, to the sixth fiber 656 and the power out terminal 662 on the sixth lamina.

It's clear that a forward current could flow through a plurality of fibers and junctions formed between two adjacent fibers seen as 651, 652, and 652, 653, and 653, 654, and 654, 655 and 655, 656. There are a plurality of fibers on each lamina so that there are a plurality of junctions formed between two adjacent laminae, and there are a plurality of laminae in the multi-lamina composite so that there are a plurality of collective junctions formed between two adjacent laminae in the multi-lamina composite.

According to some references to the Chung's report, the backward current induced in the multi-lamina composite by the input is observed.

Obviously, the multi-lamina composite can also be a four-terminal backward current decoupler. Both the two-lamina and multi-lamina composites satisfy the definition of the backward current decoupler defined above equation (24).

The phenomenon of backward current discovered in the two-lamina and multi-lamina composites of the Chung's report “apparent negative electrical resistance in carbon fiber composites” can be interpreted by the geometric structure of the fibers and the electrical contacts between two fibers respectively on the different laminae featuring that current will change its direction from flowing through a fiber of a lamina into another fiber of another adjacent lamina, or, in other words, current will flow through a fiber along its axial direction changing into its radial direction. The geometric structure of the fiber characterizes its length is a lot larger than its diameter so that the geometric structure of the fiber features its directionality for current flowing through. Current flowing through a fiber-type device implies better current directionality. The electrical contact between two fibers on different laminae features point-to-point contact which implys better current directionality in the junction than large area or bulk contact. There are a plurality of fibers on each lamina obtaining a plurality of point-to-point contacts among fibers so that the coupled area of two laminae can be viewed to be built by a plurality of point-to-point contacts, which is a concept of discretization against the concept of bulk.

The structures of a plurality of discrete fibers paralleled one by one on a lamina and a plurality of point-to-point discrete contacts formed between two laminae of the two-lamina and multi-lamina composites provide better current directionality than that of bulk contact. It's obviously, current flowing through discrete fibers has better current directionality than that of a bulk body. A bulk body can be viewed to have continuously numerous fibers in all the direction so that current flowing disorderly in a bulk body will generate internal interactions against with each other.

The phenomenon of backward current discovered in the two-lamina and multi-lamina composites of the Chung's report “apparent negative electrical resistance in carbon fiber composites” can be made sense by the geometric structure of the fibers for providing better current directionality and current changing its axial direction into radial direction in a fiber for providing a chance to decouple the induced backward current entirely.

To more intuitively explain the phenomenon of the backward current in the two-lamina composite, FIG. 61 has repeated a two-lamina composite of Chung's report of which a first and second laminae 644, 645 are seen. FIG. 61 has also shown a first loop 646 formed by two terminals of the two-lamina composite and a second loop 647 formed by the other two terminals of the two-lamina composite for the induced backward current as revealed in the experimental set-up shown in FIG. 2 of the Chung's report. A power source 648 generates forward current input flowing through the first loop 646 and the backward current induced by the input flows through the second loop 647. A first arrow 649 indicates the direction of current flowing through the second lamina 645 in the first loop 646.

We can image that current flowing in the first loop 646 has decided the current directionality in the second lamina 645.

Obviously, the induced backward current flowing through the second loop 647 in the collective junction formed by the coupling of the first and second laminae 644, 645 will be opposite to the forward current flowing through the first loop 646 in the collective junction, which intuitively explains the phenomenon of backward current induced in the junction. The fiber structure, the materials made up the fiber and current changing direction in the structure of the two-lamina and multi-lamina composites might make the magic possible. For example, if the two laminae 644 and 645 shown in FIG. 61 are bulk bodies instead of fiber structure we might not have significantly observable backward current decoupled. The speculation about the phenomenon of the backward current described above will not limit the present invention.

The current-voltage characteristics of the two-lamina composite revealed in the Chung's report “apparent negative electrical resistance in carbon fiber composites” has shown very good linearility, but the non-linear dynamical variations of the resistance of both the two-lamina and multi-lamina composites are important and needed in the present invention, which will be explained later.

Using a junction formed by two fibers respectively on two different laminae as an example, the problem of linear resistance of the two-lamina and multi-lamina composites can be solved by having each junction formed by the electrical contact of two fibers respectively on two different laminae comprise a PDR device and a NDR device electrically connected in series so that current flowing through the two fibers surely goes through a PDR device and a NDR device. A junction formed by the electrical contact of two fibers respectively on two different laminae comprises a PDR device and a NDR device electrically connected in series can be called PNDR junction in the invention.

And, further, the problem of linear resistance of the two-lamina and multi-lamina composites can also be solved by having a junction formed by the electrical contact of two fibers respectively on two different laminae comprise a PDR device, a NDR device and a pure resistor electrically connected in series with each other so that current flowing through the two fibers surely goes through a PDR device, a NDR device and a pure resistor. A junction formed by the electrical contact of two fibers respectively on two different laminae comprises a PDR device, a NDR device and a pure resistor electrically connected in series can be called PPNDR junction in the invention. The pure resistor in the embodiment can be used for providing an expective resistance level for the PPNDR junction. It's obviously, the resistances of the PNDR and PPNDR junctions will dynamically vary and are not linear any more.

There are a plurality of fibers on each lamina so that there can be a plurality of junctions, PNDR junctions or PPNDR junctions formed between two laminae. A two-lamina composite comprising a plurality of PNDR or PPNDR junctions is respectively called PNDR or PPNDR two-lamina composite in the invention. A multi-lamina composite comprising a plurality of PNDR or PPNDR junctions is respectively called PNDR or PPNDR multi-lamina composite in the invention. It's obviously, the resistances of the PNDR two-lamina and PNDR multi-lamina composites are dynamically variable and are not linear any more. The resistances of the PPNDR two-lamina and PPNDR multi-lamina composites are dynamically variable with an expective resistance level depending on the pure resistor used.

FIG. 6f has shown a first fiber 651 and a second fiber 652 are crossed with each other through a third and fourth devices 653 and 654. At least a portion of a surface of the first fiber 651 and the second fiber 652 are respectively covered with the third device 653 and the fourth device 654, and both the first and second fibers 651, 652 after covering are still fiber-type. The third device 653 and the fourth device 654 contain a PDR device and a NDR device, which means that if the third device is a PDR device then the fourth device is a NDR device, or if the third device is a NDR device then the fourth device is a PDR device. A line 666 expresses that current flowing between two fibers 651, 652 will go through the third and fourth device 653, 654.

FIG. 6g has shown a first fiber 655 and a second fiber 658 are crossed with each other through a third and fourth devices 656 and 657. At least a portion of the first fiber 655 is covered with the third device 656 and at least a portion of the third device 656 is then covered with the fourth device 657. The third device 656 and the fourth device 657 contain a PDR device and a NDR device. The first fiber 655 after covering is still fiber-type. A line 667 indicates that current flowing between two fibers 655, 658 will go through the third and fourth device 656, 657. Two embodiments respectively shown in FIGS. 6f and 6g have demonstrated to realize a PNDR junction formed by two cross-ply fibers.

FIG. 6h has shown a first fiber 659 and a second fiber 662 are crossed with each other through a third, fourth and fifth devices 660, 661 and 663. At least a portion of the first fiber 659 is covered with the third device 660 and at least a portion of the third device 660 is then covered with the fourth device 661. At least a portion of the second fiber 662 is covered with the fifth device 663. Both the first and second fibers 659, 663 after covering are still fiber-type. The third device 660, the fourth device 661 and the fifth device 663 contain a PDR device, a NDR device and a pure resistor, which means that the third device is a PDR device, the fourth device is a NDR device and the fifth device is a pure resistor, or the third device is a PDR device, the fourth device is a pure resistor and the fifth device is a NDR, or the third device is a NDR device, the fourth device is a PDR device and the fifth device is a pure resistor, or the third device is a NDR device, the fourth device is a pure resistor and the fifth device is a PDR device, or the third device is a pure resistor, the fourth device is a PDR device and the fifth device is a NDR device, or the third device is a pure resistor, the fourth device is a NDR device and the fifth device is a PDR device. A line 668 indicates that current flowing between two fibers 659, 662 will go through the third, fourth and fifth devices 660, 661 and 663. An embodiment shown in FIG. 6h has demonstrated to realize a PPNDR junction formed by two cross-ply fibers.

FIG. 6r has shown a first fiber 645 and a second fiber 649 are crossed with each other through a third, fourth and fifth devices 646, 647 and 648. At least a portion of the first fiber 645 is covered with the third device 646 and at least a portion of the third device 646 is then covered with the fourth device 647 and at least a portion of the fourth fiber 647 is covered with the fifth device 648. The third device 646, the fourth device 647 and the fifth device 648 contain a PDR device, a NDR device and a pure resistor. Current flowing the first and second fibers 645, 649 will go through a PDR device, a NDR device and a pure resistor. The first fiber 645 after covering is still fiber-type. Two embodiments respectively shown in FIGS. 6h and 6r have demonstrated to realize a PPNDR junction formed by two fibers.

The PDR device can be easily found anywhere but not the NDR device. If a junction device originally contains a PDR device then only a NDR device is needed to be added to the junction. For example, if either one of the first and second fibers of FIG. 6r has PDR property then it can play the role of the PDR device.

A multi-layer fiber can be manufactured by using a method of ioned thin-film. FIG. 6i has shown a second thin film 688 is covered on a third thin film 689 and a first film 687 is covered on the second film 688. FIG. 6j has shown the three-layer thin film shown in FIG. 6i are rolled over into a shape of a fiber. The first, second and third thin films 687, 688 and 689 contain a PDR device, a NDR device and a fiber.

The definition applied to the PNDR and PPNDR two-lamina and multi-lamina composites above can be extended to the backward current decoupler. If a backward current decoupler comprises a PDR and NDR devices electrically connected in series for both forward and induced backward currents flowing through, the backward current decoupler can be called PNDR backward current decoupler in the present invention. If a backward current decoupler comprises a PDR device, a NDR device and a pure resistor electrically connected in series with each other for both forward and induced backward currents flowing through, the backward current decoupler can be called PPNDR backward current decoupler in the present invention.

The resistance of the PNDR backward current decoupler including the PNDR two-lamina composite and PNDR multi-lamina composite will be dynamically variable and not linear any more. The resistance of the PPNDR backward current decoupler including the PPNDR two-lamina composite and PPNDR multi-lamina composite will be dynamically variable with an expective resistance level depending on the pure resistor used.

The more laminae a multi-lamina composite has the bigger resistance the multi-lamina composite will have so that an expective resistance level of a multi-lamina composite can also be obtained depending on the numbers of the laminae made of the multi-lamina composite.

The PNDR junctions formed between two fibers respectively shown in FIGS. 6f and 6g and the PPNDR junction formed between two fibers shown in FIGS. 6h and 6r have the structure of capacitor so that the PNDR two-lamina composite, PNDR multi-lamina composite, PPNDR two-lamina composite and PPNDR multi-lamina composite can be viewed as a capacitor matrix having very good capacitive property.

The two coupled fibers shown in FIG. 6f can be viewed as two capacitors electrically couple together through their big area body contacts.

Equation (1) has revealed that capacitance of a capacitor is reversely proportional to exciting frequency and resistance so that the capacitances respectively of the PNDR two-lamina composite, PNDR multi-lamina composite, PPNDR two-lamina composite and PPNDR multi-lamina composite will dynamically vary in a very large-scale range due to violently variable resistance of the coupled PDR and NDR devices and junction effect formed between two fibers through their large area body contacts. Obviously, with more numbers of laminae and more fibers on each lamina the capacitance of the PNDR two-lamina composite, PNDR multi-lamina composite, PPNDR two-lamina composite and PPNDR multi-lamina composite will vary in a significantly large-scale range.

According to the discussion revealed above the PNDR two-lamina composite, PNDR multi-lamina composite, PPNDR two-lamina composite and PPNDR multi-lamina composite have very good properties of variation in both the resistance and capacitance so that they can be high-sensitivity sensors and the sensed signal will be reflected by the induced backward current. And further, as revealed by equations (19) and (20), the impedance functions of the PDR and NDR devices in those decouplers can respond with the parameter ω, which can be temperature field T, magnetic field flux intensity B, optical field intensity I, electrical field such as voltage v, current i, frequency f or electrical power P, mechanical field such as magnitude of force F, vibration force, and so on, or any combinations of them listed above. If those decouplers are affected by any field listed above then the resistance and capacitance of the decoupler vary and the decoupled backward current will reflect such variations. In other words, the PNDR backward current decoupler including the PNDR two-lamina composite and PNDR multi-lamina composite, and the PPNDR backward current decoupler including the PPNDR two-lamina composite and PPNDR multi-lamina composite can be a thermal sensor, an electrical field sensor, a magnetic field sensor, a mechanical field sensor, a vibration sensor, an optical sensor or any combinations of them. The sensed signal will be output by the induced backward current when the backward current decoupler is applied by any field listed above. The backward current decoupler including two-lamina and multi-lamina composites, the PNDR backward current decoupler including PNDR two-lamina and PNDR multi-lamina composites and the PPNDR backward current decoupler including PPNDR two-lamina and PPNDR multi-lamina composites can be used as a sensor, but the PNDR backward current decoupler including PNDR two-lamina and PNDR multi-lamina composites and the PPNDR backward current decoupler including PPNDR two-lamina and PPNDR multi-lamina composites have better sensitivity.

FIG. 6q has shown a sensor matrix made by a plurality of backward current decouplers in parallel and/or in series. FIG. 6q has shown 9 decouplers in 3×3 matrix powered by a power source 680. Terminal 1 and terminal 2 of each decoupler are for forward current loop and terminal 3 and terminal 4 of each of the decouplers are for backward current loop. When a backward current decoupler is affected the sensed signal will be output by the induced backward current. A sensor matrix can be used to establish a sensing area.

And further, a new p-n junction device is revealed. The term “p-n” is respectively associated with p-type and n-type semiconductor devices (or respectively p-type and n-type devices in short). Referring back to the PNDR or PPNDR junction formed between two crossed fibers respectively shown in FIGS. 6f, 6g, 6h and 6r, a new p-n junction device can be obtained if the first fiber 651 and second fiber 652 contain a p-type and a n-type devices. It means that the first fiber 651 is a p-type or n-type device and the second fiber 652 is the other one of the p-type or n-type device to form a p-n junction. The PNDR junction shown in FIGS. 6f and 6g is called PNDR p-n junction in the invention if the first fiber and second fiber contain a p-type and a n-type devices and the PPNDR junction shown in FIGS. 6h and 6r is called PPNDR p-n junction in the invention if the first fiber and second fiber contain a p-type and a n-type devices.

The inventive PNDR and PPNDR p-n junction devices have some advantages, for example, they have more capacitive property than current p-n junction device so that it consumes less energy, they have damper built in the junction providing better frequency response, they have very sensitive tunneling effect due to built-in PDR and NDR devices and the heat generated in the junction can be easier conducted out through the terminals because the terminals can physically touch the junction. And further, the inventive PNDR or PPNDR p-n junction device can be interactable with temperature field T, magnetic field flux intensity B, optical field intensity I, electrical field such as voltage v, current i, frequency f or electrical power P, mechanical field such as magnitude of force F, vibration force, and so on, or any combination of them listed above so that the p-n junction devices are field-interactable devices.

For example, if the PNDR and PPNDR p-n junction devices are respective an optical device then they can provide better lumination with less energy consumed.

An embodiment, FIGS. 6m and 6n have shown a PNDR capacitor assembly respectively in side and top views. The PNDR capacitor assembly has three laminae each of which has two capacitors. A line 677 represents current flowing through a first capacitor 671, through a second capacitor 673 and through a third capacitor 678 for sure going through a first PDR device 674, a NDR device 675 and a second PDR device 676.

Obviously, the PNDR or PPNDR capacitor assembly can be a four-terminal backward current decoupler with very good frequency responses and bandwidth. And further, the PNDR or PPNDR capacitor assembly can be a two-terminal capacitor assembly with any two terminals respectively on the different laminae and disregarding the other two terminals, for example, floating the other two terminals.

The fiber is not limited. The PDR, NDR and pure resistor are not limited.

What is claimed is:

1. A junction device, comprising:
a first fiber-type device;
a second fiber-type device; and
a third device;
wherein the first fiber-type device, the second fiber-type device and the third device are electrically connected in series with each other, and at least a portion of a surface of the first fiber-type device or the second fiber-type device is covered with the third device, and the first fiber-type device or second fiber-type device with the covering is fiber-type, and the first fiber-type device and the second fiber-type device are crossed with each other through the third device, and current flowing between the first fiber-type device and the second fiber-type device goes through the third device.

2. The junction device of claim 1, wherein the first and second fiber-type devices comprises a p-type and a n-type devices, and the third device is a NDR device, and the impedance function of the NDR device varies with temperature field, magnetic field flux intensity, optical field intensity, electrical field such as voltage, current, frequency or electrical power, mechanical field such as magnitude of force, vibration force or any combinations of them.

3. The junction device of claim 1 further comprising a fourth device, wherein the first fiber-type device, the second fiber-type device, the third device and the fourth device are electrically connected in series with each other, and the first fiber-type device and the second fiber-type device are crossed with each other through the third and fourth devices, and current flowing between the first fiber-type device and the second fiber-type device goes through the third and fourth devices.

4. The junction device of claim 3, wherein the first fiber-type device and the second fiber-type device comprise a p-type device and a n-type device, and the third device and fourth device comprise a PDR device and a NDR device, and the impedance function of the PDR device and NDR device vary with temperature field, magnetic field flux intensity, optical field intensity, electrical field such as voltage, current, frequency or electrical power, mechanical field such as magnitude of force, vibration force or any combinations of them.

5. The junction device of claim 4, wherein at least a portion of a surface of the first fiber-type device is covered with the third device and at least a portion of a surface of the second fiber-type device is covered with the fourth device, and the first fiber-type device with the covering and the second fiber-type device with the covering are fiber-type.

6. The junction device of claim 4, wherein at least a portion of a surface of the first fiber-type device or the second fiber-type device is covered with the third device and at least a portion of a surface of the third device is covered with the fourth device, and the first fiber-type device with the covering or the second fiber-type device with the covering is fiber-type.

7. The junction device of claim 1, further comprising a fifth device, wherein the first fiber-type device, the second fiber-type device, the third device, the fourth device and the fifth device are electrically connected in series with each other, and the first fiber-type device and the second fiber-type device are crossed with each other through the third, fourth and fifth devices, and current flowing between the first fiber-type device and the second fiber-type device goes through the third, fourth and fifth devices.

8. The junction device of claim 7, wherein the first fiber-type device and the second fiber-type device comprise a p-type device and a n-type device, and the third, fourth and fifth devices comprise a PDR device, a NDR device and a pure resistor, and the impedance function of the PDR device and NDR device vary with temperature field, magnetic field flux intensity, optical field intensity, electrical field such as voltage, current, frequency or electrical power, mechanical field such as magnitude of force, vibration force or any combinations of them.

9. The junction device of claim 8, wherein at least a portion of a surface of the first fiber-type device or the second fiber-type device is covered with the third device, and at least a portion of a surface of the third device is covered with the fourth device, and at least a portion of a surface of the fourth device is covered with the fifth device, and the first fiber-type device with the covering or the second fiber-type device with the covering is fiber-type.

10. The junction device of claim 8, wherein at least a portion of a surface of the first fiber-type device or the second fiber-type device is covered with the third device, and at least a portion of a surface of the third device is covered with the fourth device, and at least a portion of a surface of the uncovered first fiber-type device or second fiber-type device is covered with the fifth device, and the first fiber-type device with the covering and the second fiber-type device with the covering are fiber-type.

11. An assembly, comprising:
a plurality of first paralleling fiber-type devices with a first end and a second end opposite to the first end;
a plurality of second paralleling fiber-type devices with a third end and a fourth end opposite to the third end, wherein the plurality of the first paralleing fiber-type devices at the first and second ends are respectively electrically connected together, and the plurality of the second paralleling fiber-type devices at the third and fourth ends are respectively electrically connected together, and the plurality of the first paralleling fiber-type devices and the plurality of the second paralleling fiber-type devices are crossed with each other through at least a device at each junction formed by two fibers to form an array of junction devices, and each of the junction devices comprises:
a first fiber-type device;
a second fiber-type device; and
a third device; wherein the first fiber-type device, the second fiber-type device and the third device are electrically connected in series with each other, and at least a portion of a surface of the first fiber-type device or the second fiber-type device is covered with the third device, and the first or second fiber-type device with the covering is fiber-type, and current flowing between the first fiber-type device and the second fiber-type device goes through the third device.

12. The assembly of claim 11, wherein the first and second fiber-type devices comprise a p-type device and a n-type device, and the third device is a NDR device, and the impedance function of NDR device varies with temperature field, magnetic field flux intensity, optical field intensity, electrical field such as voltage, current, frequency or electrical power, mechanical field such as magnitude of force, vibration force or any combinations of them.

13. The assembly of claim 11 further comprising a fourth device, wherein the first fiber-type device, the second fiber-type device, the third device and the fourth device are electrically connected in series with each other, and the first fiber-type device and the second fiber-type device are crossed with each other through the third and fourth devices, and current flowing between the first fiber-type device and the second fiber-type device goes through the third and fourth devices.

14. The assembly of claim 13, wherein the first fiber-type device and the second fiber-type device comprise a p-type device and a n-type device, and the third device and fourth device comprise a PDR device and a NDR device, and the impedance function of the PDR device and NDR device vary with temperature field, magnetic field flux intensity, optical field intensity, electrical field such as voltage, current, frequency or electrical power, mechanical field such as magnitude of force, vibration force or any combinations of them.

15. The assembly of claim 14, wherein at least a portion of a surface of the first fiber-type device is covered with the third device and at least a portion of a surface of the second fiber-type device is covered with the fourth device, and the first fiber-type device with the covering and the second fiber-type device with the covering are fiber-type.

16. The assembly of claim 14, wherein at least a portion of a surface of the first fiber-type device or the second fiber-type device is covered with the third device and at least a portion of a surface of the third device is covered with the fourth device, and the first fiber-type device with the covering or the second fiber-type device with the covering is fiber-type.

17. The assembly of claim 11, further comprising a fifth device, wherein the first fiber-type device, the second fiber-type device, the third device, the fourth device and the fifth device are electrically connected in series with each other, and the first fiber-type device and the second fiber-type device are crossed with each other through the third, fourth and fifth device, and current flowing between the first fiber-type device and the second fiber-type device goes through the third, fourth and fifth devices.

18. The assembly of claim 17, wherein the first fiber-type device and the second fiber-type device comprise a p-type device and a n-type device, and the third, fourth and fifth devices comprise a PDR device, a NDR device and a pure resistor, and the impedance function of the PDR device and NDR device vary with temperature field, magnetic field flux intensity, optical field intensity, electrical field such as voltage, current, frequency or electrical power, mechanical field such as magnitude of force, vibration force or any combinations of them.

19. The assembly of claim 18, wherein at least a portion of a surface of the first fiber-type device or the second fiber-type device is covered with the third device, and at least a portion of a surface of the third device is covered with the fourth device, and at least a portion of a surface of the fourth device is covered with the fifth device, and the first fiber-type device with the covering or the second fiber-type device with the covering is fiber-type.

20. The assembly of claim 18, wherein at least a portion of a surface of the first fiber-type device or the second fiber-type device is covered with the third device, and at least a portion of a surface of the third device is covered with the fourth device, and at least a portion of a surface of the uncovered first fiber-type device or second fiber-type device is covered with the fifth device, and the first fiber-type device with the covering and the second fiber-type device with the covering are fiber-type.

21. A sensor, comprising:
a plurality of first paralleling fiber-type devices with a first end and a second end opposite to the first end;
a plurality of second paralleling fiber-type devices with a third end and a fourth end opposite to the third end, wherein the plurality of the first paralleing fiber-type devices at the first and second ends are respectively electrically connected together, and the plurality of the second paralleing fiber-type devices at the third and fourth ends are respectively electrically connected together, and a forward current flows through two ends respectively of the first paralleling fiber-type devices and the second paralleling fiber-type devices then a backward current is induced by the input to provide sensing signal flowing through the other two ends respectively of the first paralleling fiber-type devices and the second paralleling fiber-type devices, and the plurality of the first paralleling fiber-type devices and the plurality of the second paralleling fiber-type devices are crossed with each other through at least a device to form an array of junction devices, and each of the junction devices comprises:
a first fiber-type device;
a second fiber-type device; and
a third device; wherein the first fiber-type device, the second fiber-type device and the third device are electrically connected in series with each other, and at least a portion of a surface of the first fiber-type device or the second fiber-type device is covered with the third device, and the first or second fiber-type device with the third device covering is fiber-type, and current flowing between the first fiber-type device and the second fiber-type device goes through the third device.

22. The sensor of claim 21, wherein the third device is a NDR device, and the impedance function of NDR device varies with temperature field, magnetic field flux intensity, optical field intensity, electrical field such as voltage, current, frequency or electrical power, mechanical field such as magnitude of force, vibration force or any combinations of them.

23. The sensor of claim 21, further comprising a fourth device, wherein the first fiber-type device, the second fiber-type device, the third device and the fourth device are electrically connected in series with each other, and the third device and fourth device comprise a PDR device and a NDR device, and the impedance function of the PDR device and NDR device vary with temperature field, magnetic field flux intensity, optical field intensity, electrical field such as voltage, current, frequency or electrical power, mechanical field such as magnitude of force, vibration force or any combinations of them.

24. The assembly of claim 23, wherein at least a portion of a surface of the first fiber-type device is covered with the third device and at least a portion of a surface of the second fiber-type device is covered with the fourth device, and the first fiber-type device with the covering and the second fiber-type device with the covering are fiber-type.

25. The assembly of claim 23, wherein at least a portion of a surface of the first fiber-type device or the second fiber-type device is covered with the third device and at least a portion of a surface of the third device is covered with the fourth device, and the first fiber-type device with the covering or the second fiber-type device with the covering is fiber-type.
